(19) United States
(12) Patent Application Publication
(10) Pub. No.: US 2026/0053038 A1
(43) Pub. Date: Feb. 19, 2026

(54) SEMICONDUCTOR SUBSTRATE INCLUDING SEMICONDUCTOR CHIP

(71) Applicant: Samsung Electronics Co., Ltd., Suwon-si (KR)

(72) Inventors: Dongwoo KIM, Suwon-si (KR); Seyeong SEOK, Suwon-si (KR); Daseul LEE, Suwon-si (KR); Jonghyeon CHANG, Suwon-si (KR)

(73) Assignee: Samsung Electronics Co., Ltd., Suwon-si (KR)

(21) Appl. No.: 19/293,126

(22) Filed: Aug. 7, 2025

(30) Foreign Application Priority Data
Aug. 14, 2024 (KR) 10-2024-0109115

(51) Int. Cl. H01L 23/00; H01L 21/683; H01L 25/065; H01L 25/18; H10B 80/00

(52) U.S. Cl. CPC H01L 24/14; H01L 21/6836; H01L 25/0657; H01L 25/18; H10B 80/00; H01L 2221/68327; H01L 2224/06131; H01L 2224/06179; H01L 2225/06513; H01L 2225/06517; H01L 2225/06541; H01L 2924/3512

(57) ABSTRACT

A semiconductor substrate including a front side and a backside and including a good die region having a plurality of semiconductor chips, a dummy die region having a plurality of dummy chips in an arc shape along an outer portion of the good die region, a plurality of first bump pads at a first interval on the backside of each of the plurality of semiconductor chips, and a plurality of second bump pads at a second interval on the backside of at least one of the plurality of dummy chips. The second interval is smaller than the first interval. The plurality of first bump pads are in a first matrix arrangement and the plurality of second bump pads are alternately arranged in a second matrix arrangement, the second matrix arrangement including both the first matrix arrangement and the first matrix arrangement shifted by a desired distance in a horizontal direction.

### CROSS-REFERENCE TO RELATED APPLICATION

This application claims priority under 35 U.S.C. § 119 to Korean Patent Application No. 10-2024-0109115, filed on Aug. 14, 2024, in the Korean Intellectual Property Office, the disclosure of which is incorporated herein by reference in its entirety.

### BACKGROUND

Example embodiments are directed to a semiconductor substrate including a dummy chip and a semiconductor chip.

In the field of electronic products, the demand for portable devices is increasing rapidly, and it is advantageous to reduce size and weight of electronic components. To realize the miniaturization and to obtain light weight electronic components, it is desirable that semiconductor packages in electronic components have a smaller volume and process high-capacity data. To obtain semiconductor packages that have highly integrated, a plurality of semiconductor chips may be formed by dicing a semiconductor substrate, and each of the plurality of semiconductor chips may be manufactured to be a semiconductor package.

### SUMMARY

Example embodiments of the inventive concepts provide a semiconductor substrate in which an area of a plurality of bump pads disposed in a dummy chip may be greater than a semiconductor chip per the same unit area in a backside of the semiconductor substrate, and thus, an undesired stripping of a dicing film may be limited to mitigate or reduce the occurrence of cracks in a semiconductor chip, thereby improving or increasing efficiency in a subsequent processing operations.

Example embodiments of the inventive concepts are not limited thereto the example embodiments disclosed herein and, and it should be understood by those of ordinary skill in the art that the disclosed example embodiments be embodied in many other specific forms without departing from the spirit or scope of the present disclosure.

According to some example embodiments, a semiconductor substrate may include a front side and a backside, and may include a good die region where a plurality of semiconductor chips are disposed, a dummy die region where a plurality of dummy chips are disposed in an arc shape along an outer portion of the good die region, a plurality of first bump pads arranged at a first interval on the backside of each of the plurality of semiconductor chips, and a plurality of second bump pads arranged at a second interval on the backside of at least one of the plurality of dummy chips. The second interval may be smaller than the first interval. The plurality of first bump pads are in a first matrix arrangement and the plurality of second bump pads are alternately arranged in a second matrix arrangement, the second matrix arrangement including both the first matrix arrangement and the first matrix arrangement shifted by a desired distance in a horizontal direction.

According to some example embodiments, a semiconductor substrate may include a front side and a backside, and may include a good die region where a plurality of semiconductor chips are disposed, a dummy die region where a plurality of dummy chips are disposed in an arc shape along an outer portion of the good die region, a plurality of first bump pads arranged at a first interval on the backside of each of the plurality of semiconductor chips, a plurality of bump structures disposed on the front side of each of the plurality of semiconductor chips, a plurality of second bump pads arranged at a second interval on the backside of at least one of the plurality of dummy chips. The second interval is smaller than the first interval. The plurality of first bump pads are in a first matrix arrangement and the plurality of second bump pads are alternately arranged in a second matrix arrangement, the second matrix arrangement including both the first matrix arrangement and the first matrix arrangement shifted by a desired distance in a horizontal direction. The plurality of bump structures are absent on the front side of at least one of the plurality of dummy chips.

According to some example embodiments, a semiconductor substrate may include a front side and a backside and may include a good die region where a plurality of semiconductor chips are disposed, a dummy die region where a plurality of dummy chips are disposed in an arc shape along an outer portion of the good die region, a plurality of first bump pads arranged at a first interval on the backside of each of the plurality of semiconductor chips, a plurality of second bump pads arranged at a second interval on the backside of at least one of the plurality of dummy chips, the second interval being smaller than the first interval, a dicing film attached to the backside of the semiconductor substrate and covering the plurality of first bump pads and the plurality of second bump pads, and an adhesive film attached to the front side of the semiconductor substrate.

### BRIEF DESCRIPTION OF THE DRAWINGS

Example embodiments will be more clearly understood from the following detailed description taken in conjunction with the accompanying drawings.

FIG. 1 is a plan view illustrating a semiconductor substrate.

FIG. 2 is a flowchart illustrating a manufacturing process of a semiconductor substrate including a semiconductor chip according to some example embodiments.

FIG. 3 is a plan view illustrating a semiconductor substrate according to some example embodiments.

FIG. 4 is a cross-sectional view corresponding to line A-A′ of FIG. 3.

FIG. 5 is an enlarged plan view corresponding to a region BB of FIG. 3.

FIGS. 6 and 7 are plan views illustrating a semiconductor substrate according to some example embodiments.

FIG. 8 is a plan view illustrating a semiconductor substrate according to some example embodiments.

FIG. 9 is an enlarged plan view corresponding to a region BB of FIG. 8.

FIG. 10 is a plan view illustrating a semiconductor substrate according to some example embodiments.

FIG. 11 is a cross-sectional view corresponding to line A-A′ of FIG. 10.

FIG. 12 is an enlarged plan view corresponding to a region DD of FIG. 10.

FIGS. 13 and 14 illustrate semiconductor packages including a semiconductor chip, according to some example embodiments.

### DETAILED DESCRIPTION OF EXAMPLE EMBODIMENTS

Hereinafter, example embodiments will be described in detail with reference to the accompanying drawings.

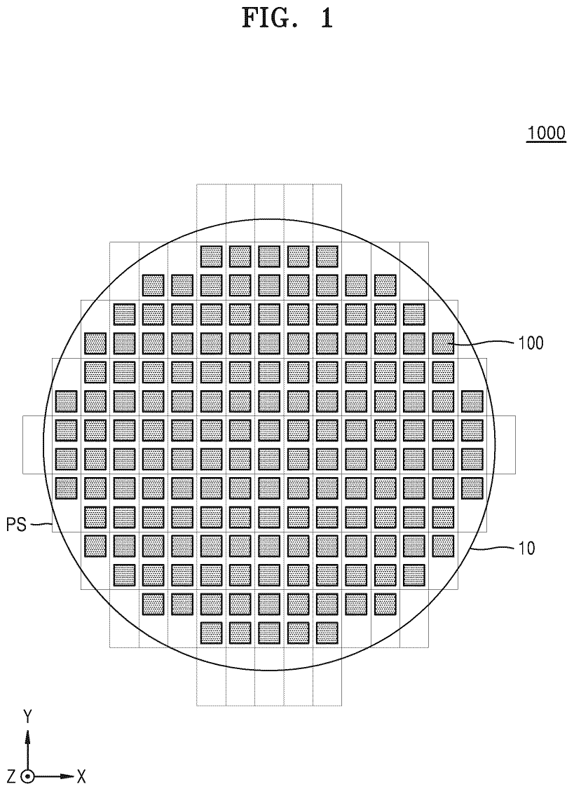

FIG. 1 is a plan view illustrating a semiconductor substrate.

Referring to FIG. 1, a semiconductor substrate 1000 including a plurality of semiconductor chips 100 is illustrated.

Generally, in the semiconductor substrate 1000, the plurality of semiconductor chips 100 may be formed on a wafer 10 through various semiconductor manufacturing processes. A photo process of exposing one photo shoot PS at the same position of a photoresist and continuously performing exposure while moving a position may be performed for forming the plurality of semiconductor chips 100. In FIG. 1, a position at which the photo shoot PS is exposed is illustrated by a thin solid line.

As described above, a pattern of a photomask may be transferred or formed on the wafer 10 by developing an exposed photoresist, and a structure based on the pattern of the photomask may be formed by a process such as chemical vapor deposition (CVD), physical vapor deposition (PVD), and electroplating.

In the semiconductor substrate 1000, the plurality of semiconductor chips 100 formed on the wafer 10 may be isolated or separated from one another through a singulation (or die cutting or dicing) process. To this end, an adhesive film may be attached to a front side of the semiconductor substrate 1000, and a dicing film may be attached to a backside of the semiconductor substrate 1000. The adhesive film may be an element for a wafer supporting system. The dicing film may support the semiconductor chip 100, until each of the semiconductor chips 100 is separated or picked up.

In a post process of the wafer supporting system, a peel-off device may be used for stripping the adhesive film attached to the front side of the semiconductor substrate 1000.

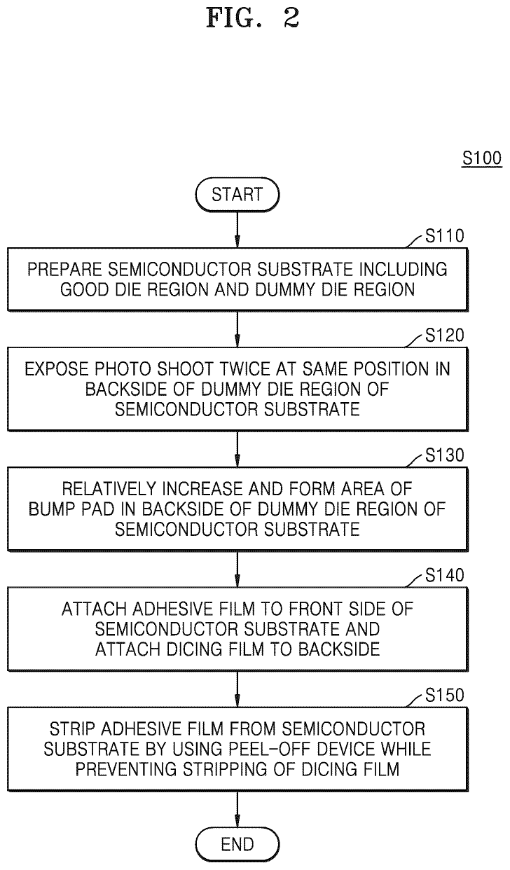

FIG. 2 is a flowchart illustrating a manufacturing process of a semiconductor substrate including a semiconductor chip according to some example embodiments. It is understood that additional operations can be provided before, during, and after the operations in FIG. 2, and some of the operations described below can be replaced or eliminated, for additional embodiments of the manufacturing process. The order of the operations/processes may be interchangeable, or two or more operations can be performed simultaneously.

Referring to FIG. 2, a manufacturing process S100 of a semiconductor substrate including a semiconductor chip may include operations S110 to S150.

The manufacturing process S100 of the semiconductor substrate including the semiconductor chip, according to some example embodiments, may include an operation S110 of preparing a semiconductor substrate including a good die region and a dummy die region, an operation S120 of exposing a photo shoot twice at the same position in a backside of the dummy die region of the semiconductor substrate, an operation S130 of relatively increasing and forming an area of a bump pad in the backside of the dummy die region of the semiconductor substrate, an operation S140 of attaching an adhesive film to a front side of the semiconductor substrate and attaching a dicing film to a backside of the semiconductor substrate, and an operation S150 of stripping the adhesive film from the semiconductor substrate by using a peel-off device while limiting stripping of the dicing film.

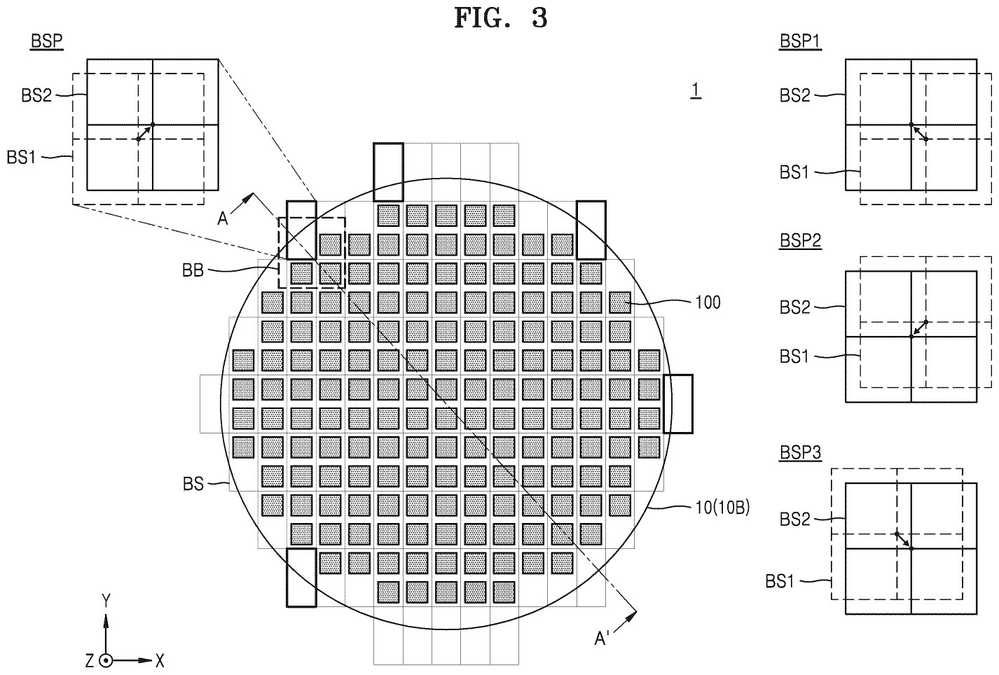

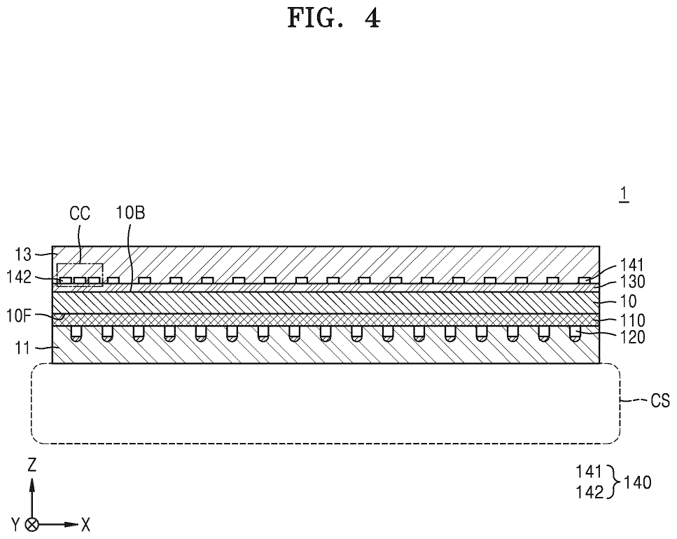

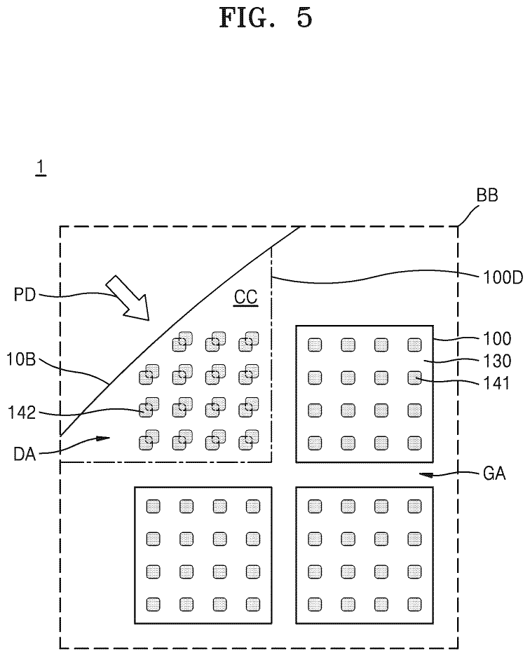

FIG. 3 is a plan view illustrating a semiconductor substrate according to some example embodiments. FIG. 4 is a cross-sectional view taken along line A-A′ of FIG. 3. FIG. 5 is an enlarged plan view corresponding to a region BB of FIG. 3.

Referring to FIGS. 3 to 5, a semiconductor substrate 1 including a plurality of semiconductor chips 100 is illustrated.

The semiconductor substrate 1 may have a circular shape having a certain thickness. The semiconductor substrate 1 may include a wafer 10. Herein, for the sake of description, the wafer 10 having a plurality of semiconductor chips 100 formed through a semiconductor manufacturing process may be referred to as the semiconductor substrate 1.

The wafer 10 may include, for example, silicon. Alternatively, the wafer 10 may include a semiconductor element, such as germanium (Ge), or a compound semiconductor such as silicon carbide (SiC), gallium arsenide (GaAs), indium arsenide (InAs), or indium phosphide (InP). Alternatively, the wafer 10 may have a silicon on insulator (SOI) structure.

In some example embodiments, the wafer 10 may include an impurity-doped well which is a conductive region or an impurity-doped structure. Also, the wafer 10 may have various device isolation structures such as a shallow trench isolation (STI) structure.

Herein, for the sake of explanation, the wafer 10 may be assumed to have a diameter of about 12 inches and include silicon (Si). It may be understood by those of ordinary skill in the art that the wafer 10 having a diameter of less or greater than 12 inches may be used in a manufacturing process of the semiconductor chips 100, and the wafer 10 including a different material instead of Si may be used in the manufacturing process of the semiconductor chips 100.

The wafer 10 may have a thickness of 0.01 mm (or about 0.01 mm) to 1 mm (or about 1 mm).

The semiconductor substrate 1 may include a front side 10F, which may be referred to as an active side, and a backside 10B, which may be referred to as an inactive side. The semiconductor chips 100 may be formed on (and subsequently isolated or separated from each other) the front side 10F of the semiconductor substrate 1. Each semiconductor chip 100 may be referred to a semiconductor device and the semiconductor device may be classified into a memory device and a logic device.

The memory device may be configured as a volatile memory device or a non-volatile memory device. The volatile memory device may include, for example, dynamic random access memory (RAM) (DRAM), static RAM (SRAM), thyristor RAM (TRAM), zero capacitor RAM (ZRAM), twin transistor RAM (TTRAM), and the like. Also, the non-volatile memory device may include, for example, flash memory, magnetic RAM (MRAM), spin-transfer torque MRAM (STT-MRAM), ferroelectric RAM (FRAM), phase change RAM (PRAM), resistive RAM (RRAM), nanotube RRAM (RRAM), polymer RAM, nano floating gate memory, holographic memory, molecular electronics memory, insulator resistance change memory, and the like.

The logic device may be implemented as, for example, a microprocessor, a graphics processor, a signal processor, a network processor, an audio processor, a video processor, an application processor, or a system on chip, but is not limited thereto. The microprocessor may include, for example, a single core or a multi-core.

In the semiconductor substrate 1, the plurality of semiconductor chips 100 may be separated from one another by scribe lanes in a matrix form. The scribe lanes may intersect with each other and extend in a first horizontal direction X and a second horizontal direction Y perpendicular to the first horizontal direction X. The scribe lane may be a rectilinear lane having a certain width.

The plurality of semiconductor chips 100 may be surrounded and arranged apart from one another by the scribe lane. The wafer 10 and various kinds of material layers formed on the wafer 10 may be cut by a cutting process performed along the scribe lane, and thus, the plurality of semiconductor chips 100 may be physically isolated or separated from one another.

A semiconductor device layer 110 may be formed on the front side 10F of the semiconductor substrate 1. The semiconductor device layer 110 may be a region where a plurality of semiconductor devices are provided or formed. Also, a plurality of bump structures 120 may be attached to a lower portion of the semiconductor device layer 110. The plurality of bump structures 120 may electrically connect the plurality of semiconductor devices to the outside. In some example embodiments, the plurality of bump structures 120 may be a plurality of solder bumps and/or a plurality of solder balls.

In some example embodiments, an adhesive film 11 may be attached to the front side 10F of the semiconductor substrate 1 to surround the plurality of bump structures 120. Also, a carrier substrate CS may be attached to the adhesive film 11. The adhesive film 11 and the carrier substrate CS may be or form a part of a wafer supporting system.

A backside wiring layer 130 may be formed on the backside 10B of the semiconductor substrate 1. The backside wiring layer 130 may be a region where a plurality of insulation layers and a plurality of wiring layers are provided or formed. Also, a plurality of bump pads 140 may be formed on the backside wiring layer 130. The plurality of bump pads 140 may be electrically connected to the plurality of semiconductor devices and/or the plurality of bump structures 120 through the backside wiring layer 130 and a through silicon via (TSV). In some example embodiments, the plurality of bump pads 140 may each be a metal pad.

In some example embodiments, a dicing film 13 may be attached to the backside 10B of the semiconductor substrate 1 to surround the plurality of bump pads 140. The dicing film 13 may be configured to support the semiconductor chips 100, until each of the semiconductor chips 100 is picked up.

The semiconductor substrate 1 may include a good die region GA where the plurality of semiconductor chips 100 are disposed. Also, the semiconductor substrate 1 may include a dummy die region DA where a plurality of dummy chips 100D are disposed in an arc shape along an outer portion of the good die region GA.

A plurality of first bump pads 141 may be arranged at a certain or desired first interval on the backside 10B of each of the plurality of semiconductor chips 100. Also, a plurality of second bump pads 142 may be arranged at a second interval, which is narrower or smaller than the first interval, on the backside 10B of at least one of the plurality of dummy chips 100D. The plurality of bump pads 140 may be configured with the plurality of first bump pads 141 and the plurality of second bump pads 142 based on a position or location of the plurality of first bump pads 141 and the plurality of second bump pads 142.

In the semiconductor substrate 1 according to some example embodiments, at least two backside shoots BS1 and BS2 may be exposed at a photoresist at the same position through repetition, on the backside 10B of at least one of the plurality of dummy chips 100D. In FIG. 3, a region where at least two backside shoots are exposed through repetition at the same position is illustrated by a thick solid line.

Furthermore, only one backside shoot BS may be exposed at the photoresist at the same position, on the backside 10B of the other of the plurality of semiconductor chips 100 and the plurality of dummy chips 100D. In FIG. 3, a region where one backside shoot is exposed at the same position is illustrated by a thin solid line.

A backside shoot 1 BS1 may be exposed at the photoresist on the at least one dummy chip 100D. Subsequently, two-time backside shoot photo process BSP of exposing a backside shoot 2 BS2, shifted in (+X, +Y) direction with respect to the backside shoot 1 BS1, at the photoresist may be performed.

In this manner, in some example embodiments, two-time backside shoot photo process BSP1 of exposing the backside shoot 2 BS2, shifted in (−X, +Y) direction with respect to the backside shoot 1 BS1, at the photoresist may be performed. In some example embodiments, two-time backside shoot photo process BSP2 of exposing the backside shoot 2 BS2, shifted in (−X, −Y) direction with respect to the backside shoot 1 BS1, at the photoresist may be performed. In some example embodiments, two-time backside shoot photo process BSP3 of exposing the backside shoot 2 BS2, shifted in (+X, −Y) direction with respect to the backside shoot 1 BS1, at the photoresist may be performed.

A photomask may be formed on the wafer 10 by developing the photoresist exposed as described above, and a structure (for example, a bump pad) based on a pattern of the photomask may be formed by a process such as CVD, PVD, or electroplating.

Therefore, the plurality of second bump pads 142 may be alternately arranged by shifting the same matrix arrangement as the plurality of first bump pads 141 by a certain or desired distance in a horizontal direction (an X and/or Y direction). In other words, the plurality of first bump pads 141 may be in a first matrix arrangement and the plurality of second bump pads 142 may be in a second matrix arrangement that includes both the first matrix arrangement and the first matrix arrangement shifted (or offset) by a desired distance in the horizontal direction and partially overlapping the first matrix arrangement.

Each of the plurality of first bump pads 141 may have a first shape, and each of the plurality of second bump pads 142 may have a second shape formed by two first shapes partially overlapping each other. In some example embodiments, the first shape may be a corner-rounded square shape, and the second shape may be a shape where corners of two square shapes overlap each other.

A ratio of an area occupied by the plurality of second bump pads 142 may be greater than a ratio of an area occupied by the plurality of first bump pads 141 per the same unit area in the backside 10B of the semiconductor substrate 1.

Stripping of the adhesive film 11 may be performed in a peel-off direction PD on portions including the plurality of dummy chips 100D where the plurality of second bump pads 142 are disposed. Also, stripping of the dicing film 13 may be limited in the peel-off direction PD.

This may be because an adhesive area between the plurality of second bump pads 142 and the dicing film 13 may be greater (or larger) than an adhesive area between plurality of first bump pads 141 and the dicing film 13, per the same unit area in the backside 10B of the semiconductor substrate 1 in the peel-off direction PD. In other words, an adhesive force of the dicing film 13 may be relatively greater at portions including the plurality of dummy chips 100D where the plurality of second bump pads 142 are disposed.

As a result, in the semiconductor substrate 1 according to some example embodiments, an area of the plurality of second bump pads 142 disposed in the dummy chip 100D at an outer portion of the semiconductor substrate 1 may be greater (or larger) than that of the plurality of first bump pads 141 disposed in the semiconductor chip 100, per the same unit area in the backside 10B of the semiconductor substrate 1. Therefore, an adhesive force between the semiconductor substrate 1 and the dicing film 13 in the peel-off direction PD may increase, and thus, undesired stripping of the dicing film 13 may be limited. Accordingly, the occurrence of a crack in the semiconductor chip 100 may be reduced, and the process efficiency of the semiconductor substrate 1 in a subsequent process (for example, a sawing process) may be improved.

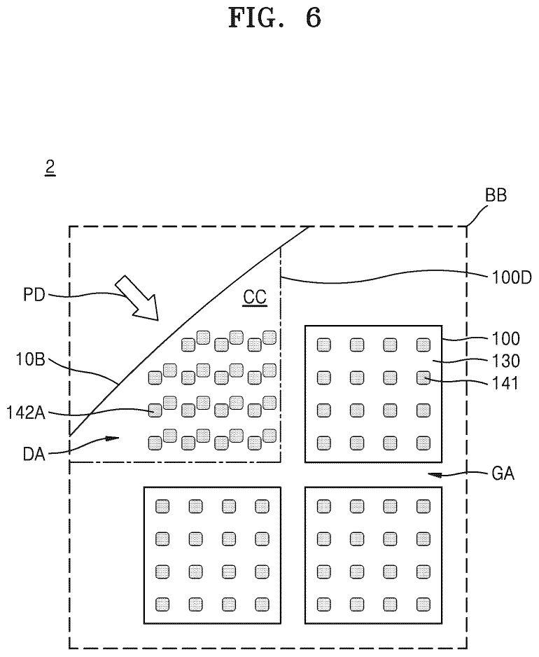

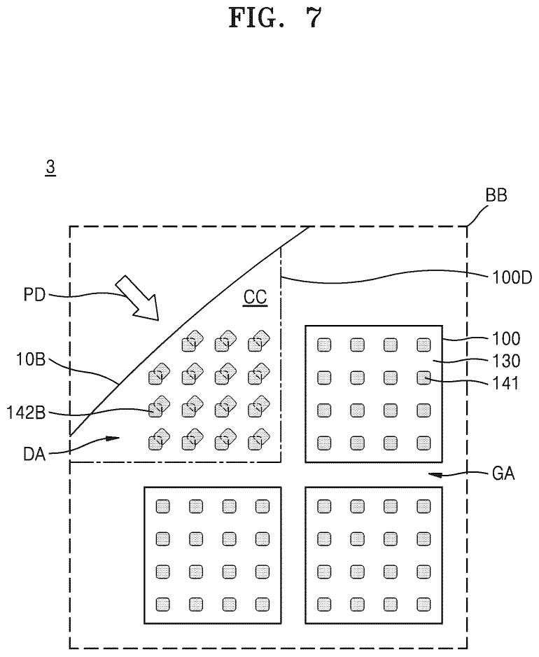

FIGS. 6 and 7 are plan views illustrating semiconductor substrates 2 and 3, according to some example embodiments.

The semiconductor substrates 2 and 3 described below and materials included in the elements may be same as or similar in some respects to the semiconductor substrate 1 of FIGS. 3 to 5, and therefore may be best understood with reference thereto where like numerals indicate like elements not described again in detail.

Referring to FIG. 6, the semiconductor substrate 2 including a plurality of semiconductor chips 100 is illustrated.

In the semiconductor substrate 2 according to some example embodiments, a plurality of first bump pads 141 may be arranged at a certain or desired first interval on backsides 10B of the plurality of semiconductor chips 100, respectively. Also, a plurality of second bump pads 142A may be arranged at a second interval, which is narrower or smaller than the first interval, on the backside 10B of at least one of the plurality of dummy chips 100D.

Each of the plurality of first bump pads 141 may have a first shape, and each of the plurality of second bump pads 142A may have a second shape obtained by pairing two first shapes. In other words, the second shape may be obtained by placing two first shapes side-by-side. In some example embodiments, the first shape may be a corner-rounded square shape, and the second shape may be a shape where two first shapes are arranged adjacent each other and separated from each other by a certain or desired distance in parallel in (+X, +Y) direction.

The number of first shapes included in the plurality of second bump pads 142A may be greater than the number of first shapes included in the plurality of first bump pads 141, per the same unit area in the backside 10B of the semiconductor substrate 2.

Stripping of the adhesive film 11 (see FIG. 4) may be performed in a peel-off direction PD on portions including the plurality of dummy chips 100D where the plurality of second bump pads 142A are disposed. Also, stripping of the dicing film 13 (see FIG. 4) may be limited in the peel-off direction PD.

Referring to FIG. 7, the semiconductor substrate 3 including a plurality of semiconductor chips 100 is illustrated.

In the semiconductor substrate 3 according to some example embodiments, a plurality of first bump pads 141 may be arranged at a certain or desired first interval on backsides 10B of the plurality of semiconductor chips 100, respectively. Also, a plurality of second bump pads 142B may be arranged at a second interval, which is narrower or smaller than the first interval, on the backside 10B of at least one of the plurality of dummy chips 100D.

Each of the plurality of first bump pads 141 may have a first shape, and each of the plurality of second bump pads 142B may have a second shape where one of two first shapes rotates clockwise (e.g., with respect to a center point) and a portion thereof is disposed to overlap the other. In other words, the second shape may be obtained from one first shape and another first shape that may be rotated clockwise (e.g., 90°) and overlapped (at least partially) with the first shape. In some example embodiments, the first shape may be a corner-rounded square shape, and the second shape may be a shape where corners and sides of two first shapes overlap each other.

A ratio of an area occupied by the plurality of second bump pads 142B may be greater than a ratio of an area occupied by the plurality of first bump pads 141, per the same unit area in the backside 10B of the semiconductor substrate 3.

Stripping of the adhesive film 11 (see FIG. 4) may be performed in a peel-off direction PD on portions including the plurality of dummy chips 100D where the plurality of second bump pads 142B are disposed. Also, stripping of the dicing film 13 (see FIG. 4) may be limited in the peel-off direction PD.

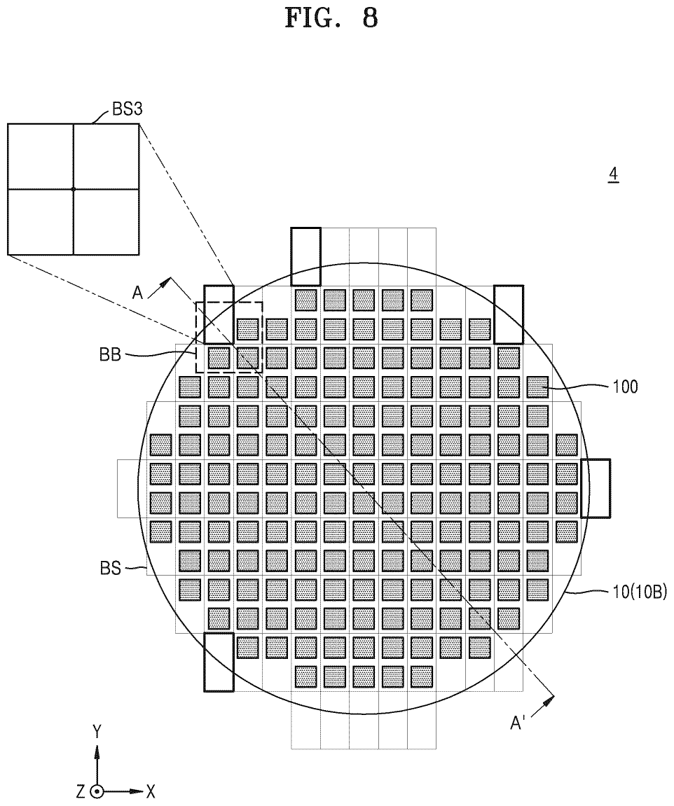

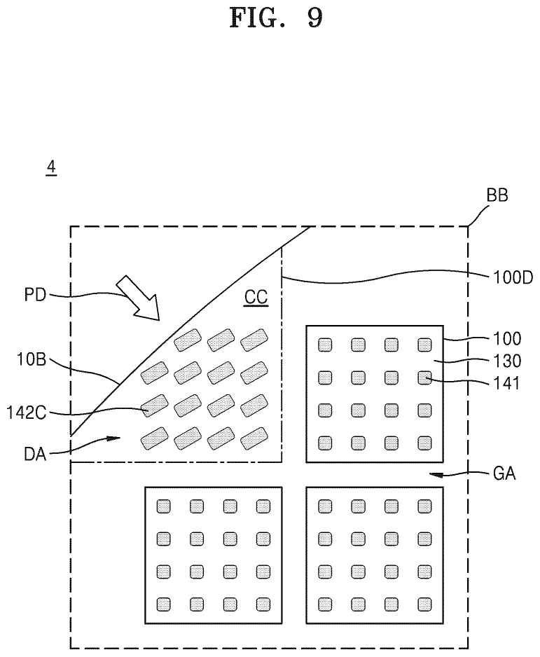

FIG. 8 is a plan view illustrating a semiconductor substrate 4 according to some example embodiments. FIG. 9 is an enlarged plan view corresponding to a region BB of FIG. 8.

The semiconductor substrate 4 described below and materials included in the elements may be same as or similar in some respects to the semiconductor substrate 1 of FIGS. 3 to 5, and therefore may be best understood with reference thereto where like numerals indicate like elements not described again in detail.

Referring to FIGS. 8 and 9, the semiconductor substrate 4 including a plurality of semiconductor chips 100 is illustrated.

In the semiconductor substrate 4 according to some example embodiments, a backside shoot 3 BS3, which differs from a backside shoot BS used in the plurality of semiconductor chips 100, may be exposed at a photoresist, on a backside 10B of at least one of a plurality of dummy chips 100D. In FIG. 8, a region where the backside shoot 3 BS3, which differs from the backside shoot BS used in the plurality of semiconductor chips 100, is exposed is illustrated by a thick solid line.

A photomask may be formed on the wafer 10 by developing the photoresist exposed as described above, and a structure (for example, a bump pad) based on a pattern of the photomask may be formed by a process such as CVD, PVD, or electroplating.

In the semiconductor substrate 4, according to some example embodiments, a plurality of first bump pads 141 may be arranged at a certain or desired first interval on backsides 10B of the plurality of semiconductor chips 100, respectively. Also, a plurality of second bump pads 142C may be arranged at a second interval, which is narrower or smaller than the first interval, on the backside 10B of at least one of the plurality of dummy chips 100D.

Each of the plurality of first bump pads 141 may have a corner-rounded square shape, and each of the plurality of first bump pads 141 may have a bar shape having a long axis and a short axis.

A ratio of an area occupied by the plurality of second bump pads 142C may be greater than a ratio of an area occupied by the plurality of first bump pads 141, per the same unit area in the backside 10B of the semiconductor substrate 4.

Stripping of the adhesive film 11 (see FIG. 4) may be performed in a peel-off direction PD on portions including the plurality of dummy chips 100D where the plurality of second bump pads 142C are disposed. Also, stripping of the dicing film 13 (see FIG. 4) may be limited in the peel-off direction PD.

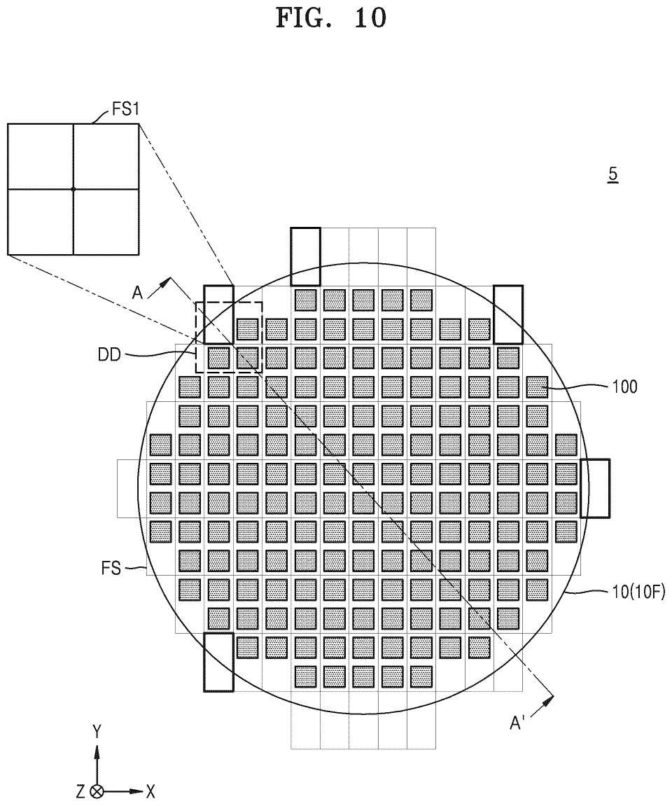

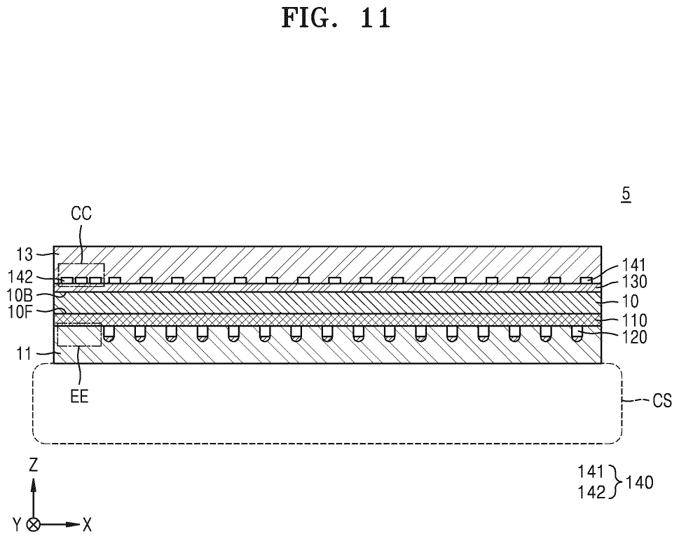

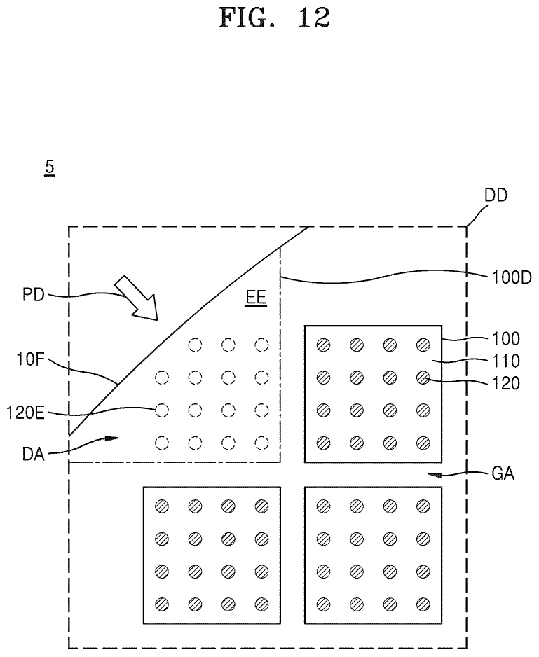

FIG. 10 is a plan view illustrating a semiconductor substrate according to some example embodiments. FIG. 11 is a cross-sectional view corresponding to line A-A′ of FIG. 10. FIG. 12 is an enlarged plan view corresponding to a region DD of FIG. 10.

The semiconductor substrate 5 described below and materials included in the elements may be same as or similar in some respects to the semiconductor substrate 1 of FIGS. 3 to 5, and therefore may be best understood with reference thereto where like numerals indicate like elements not described again in detail.

Referring to FIGS. 10 to 12, the semiconductor substrate 5 including a plurality of semiconductor chips 100 is illustrated.

In the semiconductor substrate 5 according to some example embodiments, a front-side shoot 1 FS1, which differs from a front-side shoot FS used in the plurality of semiconductor chips 100, may be exposed at a photoresist, on a front side 10F of at least one of a plurality of dummy chips 100D. In FIG. 10, a region where the front-side shoot 1 FS1, which differs from the front-side shoot FS used in the plurality of semiconductor chips 100, is exposed is illustrated by a thick solid line.

A photomask may be formed on the wafer 10 by developing the photoresist exposed as described above, and a structure (for example, a bump structure) based on a pattern of the photomask may be formed by a process such as CVD, PVD, or electroplating.

The semiconductor substrate 5 may have a circular shape having a certain thickness. The semiconductor substrate 5 may include a wafer 10.

The semiconductor substrate 5 may include a front side 10F, which may be referred to as an active side, and a backside 10B, which may be referred to as an inactive side. A semiconductor device, where the semiconductor chips 100 may be formed on (and subsequently isolated or separated from each other) the front side 10F of the semiconductor substrate 5.

A semiconductor device layer 110 may be formed on the front side 10F of the semiconductor substrate 5. The semiconductor device layer 110 may be a region where a plurality of semiconductor devices are provided. Also, a plurality of bump structures 120 may be attached to a lower portion of the semiconductor device layer 110. The plurality of bump structures 120 may electrically connect the plurality of semiconductor devices to the outside.

A plurality of bump structures 120 may be arranged at a certain or desired interval on the front side 10F of each of the plurality of semiconductor chips 100. Also, the plurality of bump structures 120 may be omitted on the front side 10F of at least one of the plurality of dummy chips 100D, and an empty space 120E may be defined.

In the semiconductor substrate 5 according to some example embodiments, similar to the semiconductor substrate 1 described above, a plurality of second bump pads 142 may be disposed on the backside 10B of at least one of the plurality of dummy chips 100D.

A ratio of an area occupied by the plurality of bump structures 120 in the plurality of dummy chips 100D may be less than a ratio of an area occupied by the plurality of bump structures 120, per the same unit area in the front side 10F of the semiconductor substrate 5.

Stripping of the adhesive film 11 may be performed in a peel-off direction PD on a portion including the plurality of dummy chips 100D where the empty space 120E is disposed. Also, stripping of the dicing film 13 may be limited in the peel-off direction PD because an adhesive force between the plurality of dummy chips 100D and the adhesive film 11 may be less than an adhesive force between the plurality of semiconductor chips 100 and the adhesive film 11, in the peel-off direction PD.

Also, an adhesive force between the plurality of dummy chips 100D and the dicing film 13 in the backside 10B of the semiconductor substrate 5 may be greater than an adhesive force between the plurality of semiconductor chips 100 and the dicing film 13, in the peel-off direction PD.

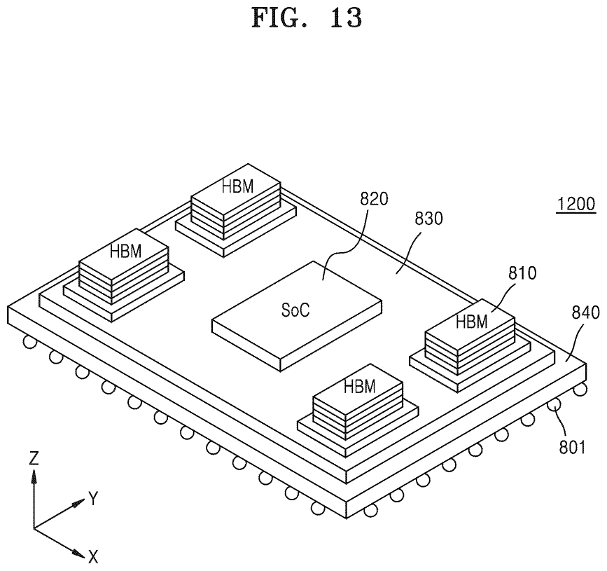

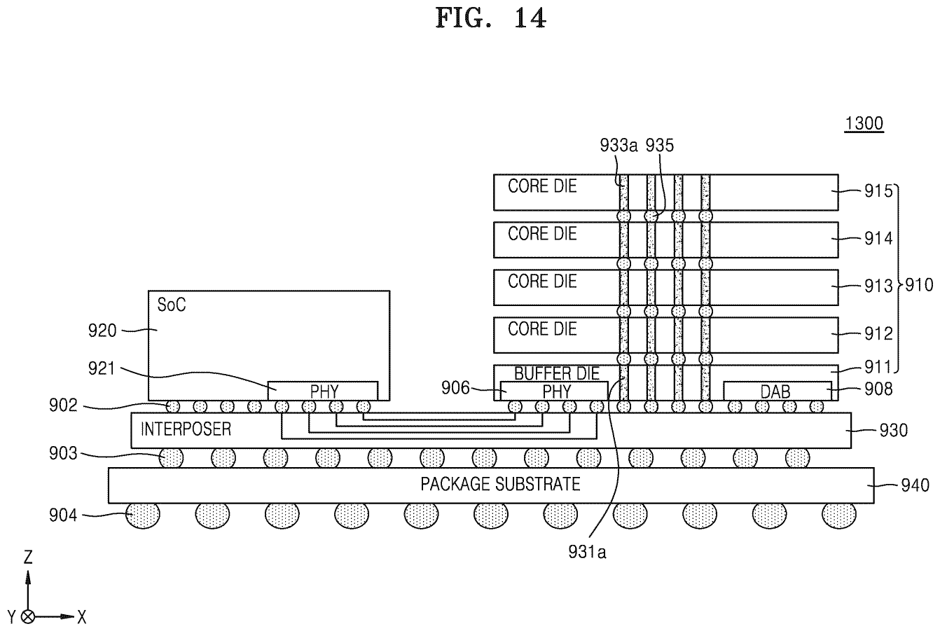

FIGS. 13 and 14 illustrate a semiconductor package including a semiconductor chip, according to some example embodiments.

Referring to FIG. 13, a semiconductor package 1200 according to some example embodiments may include a plurality of stack memory chips 810 and/or a system on chip (SoC) 820.

The plurality of stack memory chips 810 and the system on chip 820 may be stacked on an interposer chip 830, and the interposer chip 830 may be stacked on a package substrate 840.

The semiconductor package 1200 may transfer or receive signals to or from another external package or electronic devices through solder balls 801 attached to a lower portion of the package substrate 840.

Each of the plurality of stack memory chips 810 may be implemented based on a high bandwidth memory (HBM) standard. However, example embodiments of the inventive concepts are not limited thereto, and each of the plurality of stack memory chips 810 may be implemented based on graphics double data rate (GDDR), hybrid memory cube (HMC), or Wide I/O standard. Each of the plurality of stack memory chips 810 may be manufactured by using a semiconductor chip 100 included in one of the semiconductor substrates 1 to 5 according to some example embodiments described above.

The system on chip 820 may include at least one processor such as an application processor (AP), a central processing unit (CPU), and a graphics processing unit (GPU) and a memory controller for controlling the plurality of stack memory chips 810. The system on chip 820 may transfer or receive signals to or from a corresponding stack memory chip through the memory controller.

Referring to FIG. 14, a semiconductor package 1300 according to some example embodiments may include a stack memory chip 910, a system on chip (SoC) 920, an interposer chip 930, and a package substrate 940.

The stack memory chip 910 may include a buffer die 911 and core dies 912 to 915. Each of the core dies 912 to 915 may include memory cells for storing data. The buffer die 911 may include a physical layer 906 and a direct access region 908. The physical layer 906 may be electrically connected to a physical layer 921 of the system on chip 920 through the interposer chip 930. The stack memory chip 910 may receive signals from the system on chip 920 through the physical layer 906, or may transfer signals to the system on chip 920.

The direct access region 908 may provide an access path for testing the stack memory chip 910 without using the system on chip 920. The direct access region 908 may include a conductive means (for example, a port or a pin) for directly communicating with an external test device. A test signal received through the direct access region 908 may be transferred to the core dies 912 to 915 through a plurality of through via structures. To test the core dies 912 to 915, data read from the core dies 912 to 915 may be transferred to the test device through the through via structures and the direct access region 908. Therefore, a direct access test on the core dies 912 to 915 may be performed.

The buffer die 911 and the core dies 912 to 915 may be electrically connected to each other through a plurality of through via structures 931a and 933a and bumps 935. Each of the buffer die 911 and the core dies 912 to 915 may be manufactured by using a semiconductor chip 100 included in one of the semiconductor substrates 1 to 5 according to some example embodiments described above.

For example, the buffer die 911 may include a first through via structure 931a. Each of the core dies 912 to 915 may include a second through via structure 933a. The buffer die 911 may receive signals provided from the system on chip 920 to each channel through bumps 902 allocated for each channel, or may transfer signals to the system on chip 920 through the bumps 902. For example, the bumps 902 may be micro-bumps.

The system on chip 920 may execute applications supporting the semiconductor package 1300 by using the stack memory chip 910. The system on chip 920 may be manufactured by using a semiconductor chip 100 included in one of the semiconductor substrates 1 to 5 according to some example embodiments described above.

The system on chip 920 may control the overall operation of the stack memory chip 910. The system on chip 920 may include the physical layer 921. The physical layer 921 may include an interface circuit for transferring or receiving signals to or from the physical layer 906 of the stack memory chip 910. The system on chip 920 may provide various signals to the physical layer 906 through the physical layer 921. The signals provided to the physical layer 906 may be transferred to the core dies 912 to 915 through the through via structures 931a and 933a and the interface circuit of the physical layer 906.

The interposer chip 930 may connect the stack memory chip 910 to the system on chip 920. The interposer chip 930 may connect the physical layer 906 of the stack memory chip 910 to the physical layer 921 of the system on chip 920 and may provide physical paths formed by using conductive materials. Therefore, the stack memory chip 910 and the system on chip 920 may be stacked on the interposer chip and may transfer and receive signals therebetween.

The bumps 903 may be attached to an upper portion of the package substrate 940, and the solder ball 904 may be attached to a lower portion of the package substrate 940. For example, the bumps 903 may be flip chip bumps. The interposer chip 930 may be stacked on the package substrate 940 through the bumps 903. The semiconductor package 1300 may transfer or receive signals to or from external another package or electronic devices through the solder ball 904.

While several example embodiments have been provided in the present disclosure, it should be understood that the disclosed systems and methods might be embodied in many other specific forms without departing from the spirit or scope of the present disclosure. The present examples embodiments are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various example embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A semiconductor substrate including a front side and a backside, the semiconductor substrate comprising:
a good die region including a plurality of semiconductor chips;
a dummy die region including a plurality of dummy chips in an arc shape along an outer portion of the good die region;
a plurality of first bump pads at a first interval on the backside of each of the plurality of semiconductor chips; and
a plurality of second bump pads at a second interval on the backside of at least one of the plurality of dummy chips, the second interval being smaller than the first interval,
wherein the plurality of first bump pads are in a first matrix arrangement and the plurality of second bump pads are alternately arranged in a second matrix arrangement, the second matrix arrangement including both the first matrix arrangement and the first matrix arrangement shifted by a desired distance in a horizontal direction.

2. The semiconductor substrate of claim 1, wherein an area occupied by the plurality of second bump pads is larger than an area occupied by the plurality of first bump pads per a same unit area in the backside of the semiconductor substrate.

3. The semiconductor substrate of claim 1, wherein a number of second bump pads is more than a number of first bump pads per a same unit area in the backside of the semiconductor substrate.

4. The semiconductor substrate of claim 2, wherein each of the plurality of first bump pads have a first shape, and
each of the plurality of second bump pads have a second shape that includes two first shapes partially overlapping each other.

5. The semiconductor substrate of claim 2, wherein
each of the plurality of first bump pads have a first shape, and
each of the plurality of second bump pads have a second shape that includes the first shape and another first shape rotated in a clockwise direction with respect to a center point.

6. The semiconductor substrate of claim 2, wherein
each of the plurality of first bump pads have a square shape, and
each of the plurality of second bump pads have a bar shape having a long axis and a short axis.

7. The semiconductor substrate of claim 1, further comprising:
an adhesive film attached to the front side of the semiconductor substrate, and
the adhesive film is configured to be stripped in a direction of the plurality of second bump pads of the plurality of dummy chips.

8. The semiconductor substrate of claim 7, further comprising:
a dicing film attached to the backside of the semiconductor substrate such that stripping of the dicing film is limited in a direction of the plurality of second bump pads of the plurality of dummy chips.

9. The semiconductor substrate of claim 8, wherein an adhesive area between the plurality of second bump pads and the dicing film is larger than an adhesive area between plurality of first bump pads and the dicing film per a same unit area in the backside of the semiconductor substrate.

10. The semiconductor substrate of claim 9, wherein an adhesive force between the plurality of dummy chips and the dicing film is greater than an adhesive force between the plurality of semiconductor chips and the dicing film.

11. A semiconductor substrate including a front side and a backside, the semiconductor substrate comprising:
a good die region including a plurality of semiconductor chips;
a dummy die region including a plurality of dummy chips in an arc shape along an outer portion of the good die region;
a plurality of first bump pads at a first interval on the backside of each of the plurality of semiconductor chips;
a plurality of bump structures on the front side of each of the plurality of semiconductor chips; and
a plurality of second bump pads at a second interval on the backside of at least one of the plurality of dummy chips, the second interval being smaller than the first interval,
wherein the plurality of first bump pads are in a first matrix arrangement and the plurality of second bump pads are alternately arranged in a second matrix arrangement, the second matrix arrangement including both the first matrix arrangement and the first matrix arrangement shifted by a desired distance in a horizontal direction, and
the plurality of bump structures are absent on the front side of at least one of the plurality of dummy chips.

12. The semiconductor substrate of claim 11, wherein
an area occupied by the plurality of second bump pads is larger than an area occupied by the plurality of first bump pads per a same unit area in the backside of the semiconductor substrate, and
an area occupied by the plurality of bump structures in the plurality of dummy chips is less than an area occupied by the plurality of bump structures in the plurality of semiconductor chips per a same unit area in the front side of the semiconductor substrate.

13. The semiconductor substrate of claim 12, further comprising:
an adhesive film attached to the front side of the semiconductor substrate, and
the adhesive film is configured to be stripped in a direction not including the plurality of bump structures of the plurality of dummy chips.

14. The semiconductor substrate of claim 13, further comprising:
a dicing film attached to the backside of the semiconductor substrate such that stripping of the dicing film is limited in a direction of the plurality of second bump pads of the plurality of dummy chips.

15. The semiconductor substrate of claim 14, wherein, in at least one of the plurality of dummy chips, an adhesive force of the dicing film is greater than an adhesive force of the adhesive film.

16. A semiconductor substrate including a front side and a backside, the semiconductor substrate comprising:
a good die region including a plurality of semiconductor chips;
a dummy die region including a plurality of dummy chips in an arc shape along an outer portion of the good die region;
a plurality of first bump pads at a first interval on the backside of each of the plurality of semiconductor chips;
a plurality of second bump pads at a second interval on the backside of at least one of the plurality of dummy chips, the second interval being smaller than the first interval;
a dicing film attached to the backside of the semiconductor substrate and covering the plurality of first bump pads and the plurality of second bump pads; and
an adhesive film attached to the front side of the semiconductor substrate.

17. The semiconductor substrate of claim 16, wherein the plurality of first bump pads are in a first matrix arrangement and the plurality of second bump pads are alternately arranged in a second matrix arrangement, the second matrix arrangement including both the first matrix arrangement and the first matrix arrangement shifted by a desired distance in a horizontal direction.

18. The semiconductor substrate of claim 17, wherein
an area occupied by the plurality of second bump pads is larger than an area occupied by the plurality of first bump pads per a same unit area in the backside of the semiconductor substrate, and
an adhesive area between the plurality of second bump pads and the dicing film is larger than an adhesive area between the plurality of first bump pads and the dicing film per a same unit area in the backside of the semiconductor substrate.

19. The semiconductor substrate of claim 18, further comprising:
a plurality of bump structures on the front side of each of the plurality of semiconductor chips, wherein
the plurality of bump structures are absent on the front side of at least one of the plurality of dummy chips, and
in at least one of the plurality of dummy chips, an adhesive force of the dicing film is greater than an adhesive force of the adhesive film.

20. The semiconductor substrate of claim 19, wherein, in at least one of the plurality of dummy chips, the dicing film attached to the backside of the semiconductor substrate such that stripping of the dicing film is limited, and the adhesive film is attached to the front side of the semiconductor substrate such that the adhesive film is configured to be stripped.
